(19) United States
(12) Patent Application Publication
(10) Pub. No.: US 2025/0140640 A1
(43) Pub. Date: May 1, 2025

(54) SEMICONDUCTOR DEVICE WITH HEAT DISSIPATION LAYER AND METHOD OF FABRICATING THEREOF

(71) Applicant: Taiwan Semiconductor Manufacturing Company, Ltd., Hsinchu (TW)

(72) Inventors: Sam Vaziri, San Jose, CA (US); Xinyu Bao, Fremont, CA (US); Isha Datye, Hsinchu (TW)

(21) Appl. No.: 18/641,017

(22) Filed: Apr. 19, 2024

Related U.S. Application Data
(60) Provisional application No. 63/593,355, filed on Oct. 26, 2023.

(51) Int. Cl. H01L 23/373; H01L 21/768; H01L 21/8234; H01L 29/417; H01L 29/66

(52) U.S. Cl. CPC H01L 23/3732; H01L 21/76897; H10D 30/024; H10D 30/6219; H10D 84/0149; H10D 84/038

(57) ABSTRACT

One aspect of the present disclosure pertains to an integrated circuit (IC) structure and method of fabricating thereof. The IC structure includes a transistor device formed on a substrate where the transistor device having source/drain (S/D) regions and a gate structure. A multi-layer interconnect (MLI) structure including metal lines and metal vias embedded in an intermetal dielectric (IMD) layer is formed over the substrate. And a thermal dissipation layer is formed having a surface with a plurality of peaks and valleys disposed over at least a portion of the MLI structure. A bonding layer is disposed over the thermal dissipation layer and covering the plurality of peaks and valleys.

### PRIORITY DATA

This application claims the benefit of U.S. Provisional Application No. 63/593,355, filed Oct. 26, 2023, the entirety of which is herein incorporated.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology progresses, concerns of thermal dissipation of the heat generated by the semiconductor devices such as transistors increase as higher temperatures degrade device performance. This is further complicated by semiconductor devices that include multi-die such as in a stacked die configuration further limiting thermal dissipation paths. Therefore, although existing semiconductor device structures have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1A illustrates a cross-sectional view of an embodiment of a portion of a semiconductor device structure having a thermal dissipation layer, according to an embodiment of the present disclosure.

FIG. 1B illustrates a cross-sectional view of the portion of a semiconductor device structure of FIG. 1A illustrating a hot spot and thermal dissipation path, according to an embodiment of the present disclosure.

FIG. 1C illustrates a cross-sectional view of the portion of a semiconductor device structure, according to an embodiment of the present disclosure.

FIG. 2 illustrates a flow chart of an embodiment of a method of fabricating a semiconductor device having a thermal dissipation layer, according to aspects of the present disclosure.

FIGS. 3, 4A, 4B, 5, 6, 7, and 8 are cross-sectional views of an embodiment of a semiconductor structure according to interim fabrication steps corresponding the method of FIG. 2, according to some aspects of the present disclosure.

FIG. 9 illustrates a cross-sectional view of an embodiment of a semiconductor structure having a thermal dissipation layer according to aspects of the present disclosure.

FIG. 10 illustrates a cross-sectional view of an embodiment of a semiconductor structure having a plurality of thermal dissipation layers included in a multi-layer interconnect, according to aspects of the present disclosure.

FIG. 11 illustrates a cross-sectional view of an embodiment of a semiconductor structure having a first die and a second die stacked on the first die and including one or more thermal dissipation layers according to aspects of the present disclosure.

FIG. 12 illustrates a cross-sectional view of an embodiment of a semiconductor structure having a first die, a second die stacked on the first die and an additional component on the second die, the stack including one or more thermal dissipation layers according to aspects of the present disclosure.

FIG. 13 illustrates a cross-sectional view of an embodiment of a semiconductor structure having a first die and a second die stacked on the first die, the structure having a plurality of thermal dissipation layers included in a multi-layer interconnect of the first and/or second die, according to aspects of the present disclosure.

FIG. 14 illustrates a cross-sectional view of another embodiment of a semiconductor structure having a thermal dissipation layer and an overlying dielectric layer, according to aspects of the present disclosure.

FIG. 15 illustrates a cross-sectional view of yet another embodiment of a semiconductor structure having a thermal dissipation layer and an overlying dielectric layer, according to aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximate,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.25 nm to 5.75 nm where manufacturing tolerances associated with depositing the material layer are known to be +/−15% by one of ordinary skill in the art. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor structures, such as integrated circuit (IC) structures comprising one or more die to form the semiconductor structure. These structures may be referred to as 3D ICs as they integrated ICs in a vertical direction in part by stacking die. The components of the stacked structure may be connected physically and/or through electrical connections. 3D ICs provide for form factor advantages and power and performance advantages including due to the interconnect lengths between the stacked devices. One application of a 3D IC structure is a processor and one or more memory chips vertically stacked. However, the semiconductor structures, including 3D ICs can experience challenges with heat dissipation from within the structure.

Thus, some of the embodiments presented herein provide for semiconductor structures to include thermal dissipation layers, also referred to as heat spreading layers, to provide for thermal dissipation paths. In some implementations, diamond-like carbon can be used as a high thermal conductivity in a 3D IC. The present disclosure provides benefits for structures and methods that allow for high thermal conductivity between layers of the semiconductor structure (e.g., between die) for thermal management. In some embodiments, this is experienced by providing the thermally conductive material layers having an improved planarity thereby increasing suitability for a bonding to additional components (e.g., die, heat spreaders, etc.) In some implementations, this is provided by a diamond-like carbon layer in conjunction with a bonding layer (e.g., high conductivity and/or dielectric layer) such as, for example, AlN. Thus, aspects of the present disclosure may improve the junction between die in a 3D IC structure. In particular, as the diamond-like carbon layer can provide a surface of significant roughness, a bonding layer implemented according to one or more aspects of the present disclosure can address compensate for the roughness of the underlying diamond-like layer.

In the following description, front-end-of-the-line (FEOL) generally refers to portions of the circuit where functional devices such as logic and memory devices are formed. The FEOL features include the transistors and features thereof such as source/drain features, channel regions, gate structures. Device-level contacts or metal features extend to the terminals of the transistor. Back-end-of-the-line (BEOL) in the present disclosure generally refers to components formed after the FEOL features and include a multi-layer interconnect (MLI). The MLI includes a plurality of metal lines (also referred to as interconnect lines) and interposing vias that provide electrical connections including to the FEOL features. The metal lines provide for horizontal routing and the vias provide for a vertical routing to connect metal lines at different metal layers. Any number of metal layers may be used including for example, exemplary MLI may include five (5) or more metal lines vertically stacked typically referred to as M1, M2, M3, and so forth. The MLI includes dielectric or insulating materials that surround the metal lines and vias to provide for suitable direction of the signals carried in the lines, the dielectric can be referred to as an inter-metal dielectric (IMD) as discussed below.

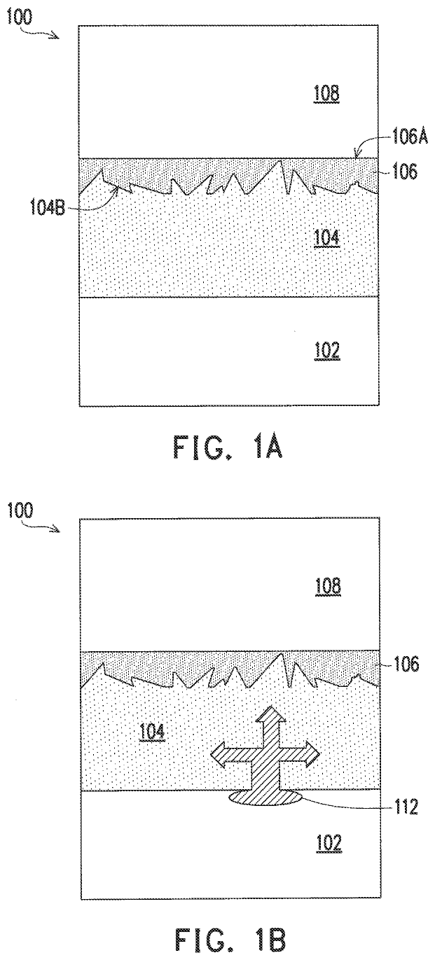

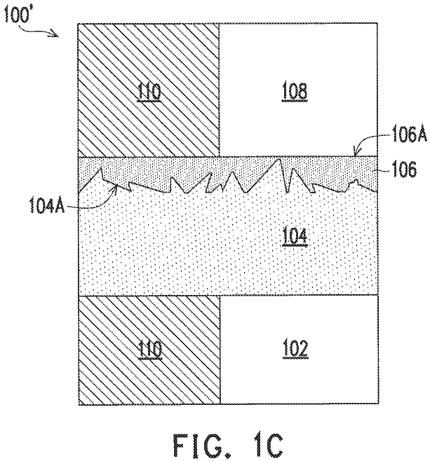

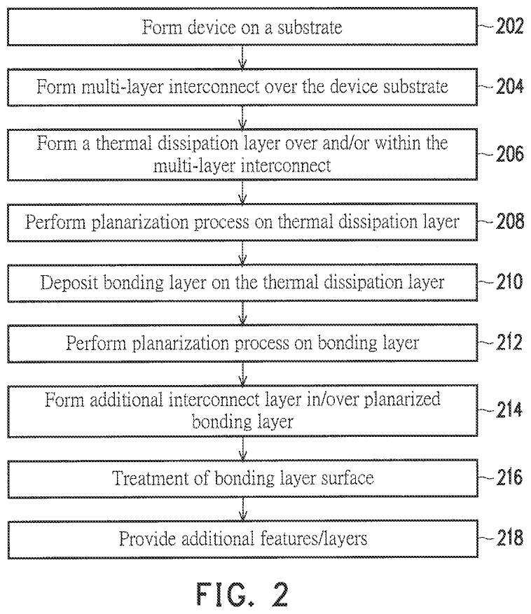

FIG. 1A illustrates a cross-sectional view of a portion of a semiconductor structure 100, according to an embodiment of the present disclosure. The semiconductor structure 100 may be a portion of an integrated circuit (IC) device and may include a plurality of device features (not shown).

As will be described further below with respect to various embodiments, the semiconductor structure 100 is formed on a semiconductor structure that has undergone FEOL processes. Such FEOL processes may form various transistors on the substrate to serve different functions. For example, these various transistors may form a central processing unit (CPU), a graphics process unit (GPU), access transistors for memory devices, image signal processing (ISP) circuitry, and/or other suitable circuitry. The transistors may be planar transistors or multi-gate transistors. A planar device refers to a device having a gate structure that engages a planar surface of a semiconductor active region. A multi-gate device generally refers to a device having a gate structure, or portion thereof, disposed over more than one side of a channel region. Fin-like field effect transistors (FinFETs) and gate-all-around (GAA) transistors are examples of multi-gate devices that have become popular and promising candidates for high performance and low leakage applications. A FinFET has an elevated channel wrapped by a gate on more than one side (for example, the gate wraps a top and sidewalls of a “fin” of semiconductor material extending from a substrate). A GAA transistor has a gate structure that can extend, partially or fully, around a channel region to provide access to the channel region on two or more sides. Because its gate structure surrounds the channel regions, a GAA transistor may also be referred to as a surrounding gate transistor (SGT) or a multi-bridge-channel (MBC) transistor. The channel region of a GAA transistor may be formed from nanowires, nanosheets, or other nanostructures and for that reasons, a GAA transistor may also be referred to as a nanowire transistor or a nanosheet transistor. The transistors are referred to herein generally, and each of the configurations discussed applies to the embodiments herein.

The semiconductor structure 100 includes a multi-layer interconnect (MLI) structure that includes multiple metal layers and is part of the BEOL as discussed above. One metal layer 102 of the MLI is illustrated and in some implementations is top or uppermost metal layer of the MLI. In some embodiments, the structure 100 is formed on a semiconductor substrate that includes silicon (Si). Alternatively or additionally, substrate includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate includes one or more group III-V materials, one or more group II-IV materials, or combinations thereof. In some implementations, the substrate is a semiconductor-on-insulator substrate, such as a silicon-on-insulator (SOI) substrate, a silicon germanium-on-insulator (SGOI) substrate, or a germanium-on-insulator (GeOI) substrate. Semiconductor-on-insulator substrates can be fabricated using separation by implantation of oxygen (SIMOX), wafer bonding, and/or other suitable methods.

The MLI of the semiconductor structure 100 includes a plurality of metal lines or layers in the MLI, for example, an MLI may typically include about five (5) to about twenty (20) metal layers (or metallization layers). Each of the metal layers of the MLI include multiple vias and metal lines embedded in a dielectric or insulating layer, which may also be referred to herein as an intermetal dielectric (IMD) layer. The vias and metal lines may be formed of titanium (Ti), ruthenium (Ru), nickel (Ni), cobalt (Co), copper (Cu), molybdenum (Mo), tungsten (W), or aluminum (Al). In an embodiment, they are formed of copper (Cu). The IMD layer may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the IMD layer includes silicon oxide.

Illustrated in FIG. 1A is a metallization layer 102. In an embodiment, the metallization layer 102 is an uppermost metal layer of an MLI of the semiconductor structure 100. In an embodiment, the metallization layer 102 is an upper-most metal layer of a die of the semiconductor structure 100 (e.g., a bottom die). The metal layer 102 may include copper (Cu). Other compositions include those discussed above titanium (Ti), ruthenium (Ru), nickel (Ni), cobalt (Co), copper (Cu), molybdenum (Mo), tungsten (W), aluminum (Al), or combinations thereof.

In the structure 100, on the metallization layer 102 is a thermal dissipation layer 104. In an embodiment, the thermal dissipation layer 104 is a diamond-like carbon layer. In some implementations, the thermal dissipation layer 104 is a poly crystalline carbon providing a diamond-like film or DLC. The diamond-like carbon may be a material that is a class of amorphous carbon materials that display some properties of diamond. The thermal dissipation layer may exhibit a low dielectric constant, such as a low-k material (e.g., lower than the dielectric constant of SiO₂, e.g., less than 3.9).

The thermal dissipation layer 104 includes a surface 104B. In some embodiments, the surface 104B has a high surface roughness. For example, in some implementations, the surface 104B has a significant roughness in that it includes peaks and valleys vertically deviating hundreds of nanometers to micrometers. In other words, the surface 104B has a root mean square (RMS value) for roughness of hundreds of nanometers to micrometers. RMS is the root mean square of vertical variations of a surface measured microscopically between its peaks and valleys. In an embodiment, a metrology tool (e.g., CD-SEM) provides measurements of the vertical distance between the peaks and valleys. In an embodiment, the surface 104B has a roughness of at least 100 nanometers (peak-to-valley RMS).

The thermal dissipation layer 104 may have a thickness of between approximately 0.5 microns (μm) and 10 μm. The thermal dissipation layer 104 may be deposited at a temperature less than or equal to approximately 400 degrees Celsius. Exemplary deposition methods include chemical vapor deposition (CVD) such as microwave plasma (MPCVD). The thermal dissipation layer 104 may comprise diamond-like carbon material having a thermal conductivity of greater than 400 W/m/K. In some implementations, the diamond-like carbon material has an advantage of a high in-plane thermal conductivity (k). In an embodiment, a seed layer may be used for the thermal dissipation layer 104. For example, a seed layer of diamond nanoparticles may be used.

On the thermal dissipation layer 104 is a bonding layer 106. The bonding layer 106 may be a dielectric material. Exemplary compositions of the bonding layer 106 include AlN, cubic BN, BP, Al₂O₃, SiN, BeO, SiO₂, or combinations thereof. In an embodiment, SiO₂, Al₂O₃ and SiN provide for enhanced adhesion. And as such in some embodiments may be used in conjunction with other materials providing desired thermal properties. In some embodiments, the composition of the bonding layer 106 has a high thermal conductivity such as a thermal conductivity (k) greater than or equal to 50 W/m/K for example for thicknesses greater than 200 nm. In an embodiment, the bonding layer 106 is AlN. In a further embodiment, the thermal conductivity (k) of the AlN is >50W/m/K for thicknesses >200 nm. In an embodiment, the bonding layer 106 is c-BN. In a further embodiment, the thermal conductivity (k) of the c-BN is several 100 s W/m/K.

In some implementations such as discussed below, a planarization process is performed on the surface of the thermal dissipation layer 104, i.e., the surface 104B, prior to depositing the bonding layer 106. In an embodiment, the surface 104B has a roughness of between 5 nm and 100 nm after the planarization process or ion milling process. The planarization process may be performed by chemical mechanical polish (CMP), ion milling, and/or other suitable processes. In other embodiments, no planarization is performed on the deposited thermal dissipation layer 104.

In an embodiment, the bonding layer 106 is deposited conformally such that it covers an entirety of the thermal dissipation layer 104. In an embodiment, the bonding layer 106 is deposited at a temperature less than approximately 400 degrees Celsius. Exemplary deposition methods include chemical vapor deposition (CVD). In an embodiment, the bonding layer 106 has a thickness less than the thermal dissipation layer 104. In some implementations, the bonding layer 106 has a thickness between approximately 100 nm to 1 μm.

In an embodiment, after deposition of the bonding layer 106, a planarization process is performed on the bonding layer 106. A planarized surface 106A may be formed. In some implementations, the roughness of the surface 106A is an RMS of less than approximately 1 nm. The planarized surface 106A provides a suitable surface for bonding additional components such as additional die, metallization layers, heat spreaders, and the like. In an embodiment, the bonding layer 106 has a surface (e.g., surface 106A) with an RMS of less than an RMS of a surface (e.g., surface 104B) of the thermal dissipation layer 104. Referring to the example of FIG. 1A, another metallization layer 108 is formed on the bonding layer 106. In an embodiment, the metallization layer 108 may be a metallization layer of another die. In an embodiment, the metallization layer 108 may be a metallization layer of a same die as that of layer 102 (e.g., Mn and M (n+1)). Thus, the bonding layer 106 may form an interface with different materials (e.g., dielectric, metal, silicon, etc). In an embodiment, the bonding layer 106 interfaces a dielectric layer of an MLI. In an embodiment, the bonding layer 106 interfaces a conductive layer of an MLI. In some implementations, the bonding layer 106 forms a hybrid bond with the conductive layer of the MLI. In an embodiment, the bonding layer 106 forms bonds with each of a conductive layer and a dielectric layer of the MLI (e.g., of a metallization layer such as M2). As illustrated below, the bonding layer 106 may bond with a silicon layer such as an overlying substrate.

It is noted that the composition of the bonding layer 106 may be selected based on several factors. First, the composition may be selected such that it provides a high enough thermal conductivity to avoid significant reduction in the overall thermal resistance of the structure. Second, the interface (between the bonding layer 106 and the thermal dissipation layer 104) and its thermal resistance may be considered. This interface may also be controlled by tuning the roughness of the thermal dissipation layer 104. For example, in an embodiment, the bonding layer 106 is c-BN and the thermal dissipation layer 104 is diamond-like carbon. These two compositions have a lattice mismatch that allows for the interface to be thermally very conductive. Third, for semiconductor structure applications with small hot spots (e.g., hot spots that are less than the thermal dissipation layer 104 thickness), the effect of the interface between the thermal dissipation layer 104 and the bonding layer 106 may become less significant or even insignificant. In such an embodiment, other dielectric materials having a lower thermal conductivity may be used for the bonding layer 106 (e.g., SiO₂, SiN). In an embodiment, the bonding layer 106 is AlN. In an embodiment, the bonding layer 106 is c-BN. The bonding layer 106 may be a multi-layer structure.

In some implementations, the thermal dissipation layer provides a high in-plane conductivity (e.g., k of greater than 400 W/m/K) and the bonding layer (e.g., AlN) provides a cross-plane conductivity k of greater than 50 W/m/K. The bonding layer does not add in-plane thermal resistance to the stack of the thermal dissipation layer and bonding layer, thereby allowing the thermal path for heat dissipation to be effective.

FIG. 1B illustrates the semiconductor structure 100 having a hot spot 112 illustrated. The hot spot 112 has a thermal path(s) extending into the thermal dissipation layer 104 and away from the hot spot 112. In some implementations, the thermal path extends into and through the bonding layer 106.

FIG. 1C illustrates an embodiment of the semiconductor structure 100′ having a dielectric or insulating layer 110 adjacent the metallization layer 108 and adjacent the metallization layer 102. In some embodiments, the insulating layer 110 above and below the thermal dissipation layer 104 are the same composition. In some embodiments, the insulating layer 110 above and below the thermal dissipation layer 104 are different compositions. The insulating layer 110 may be an insulating layer of a MLI structure and in some implementations referred to as an inter-metal dielectric (IMD). The insulating layers 110 may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. The structure 100′ of FIG. 1C and the semiconductor structure 100 of FIGS. 1A and/or 1B may be different cross-sectional views of a semiconductor structure formed on a same substrate and are illustrative only. In some implementations, only a dielectric layer such as insulating layer 110 may be formed over the bonding layer 106.

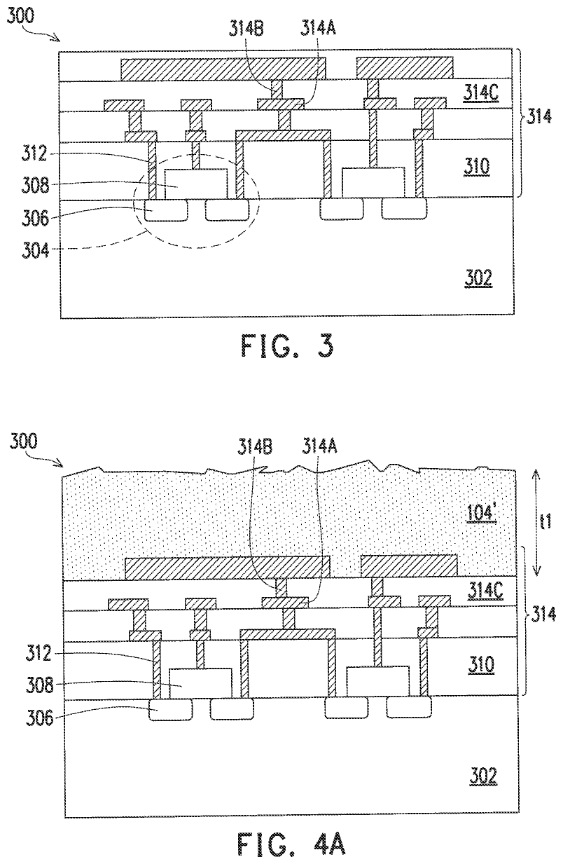

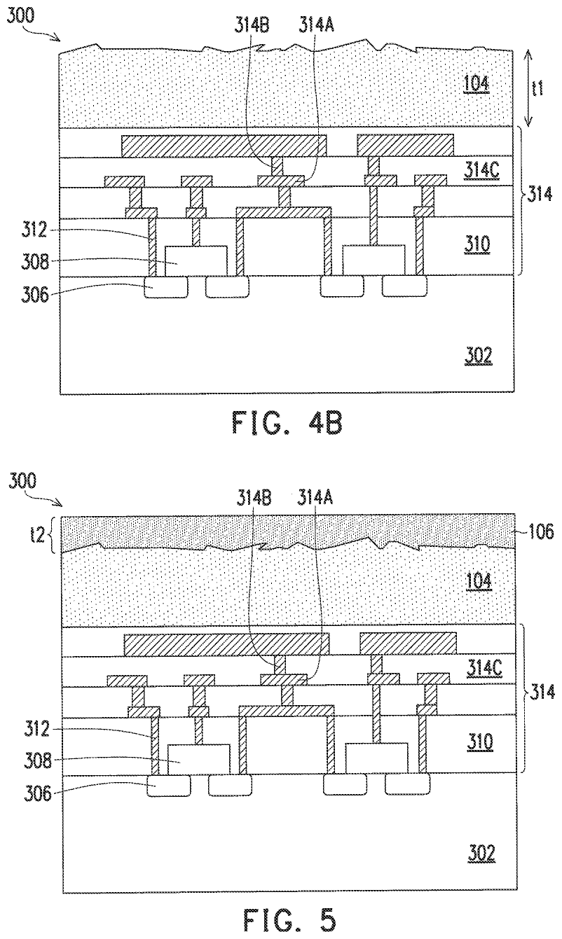

Referring now to FIG. 2, illustrated is a method 200 for forming a semiconductor structure or portion thereof. In an embodiment, the method 200 may be used to fabricate the semiconductor structure 100, discussed above with reference to FIGS. 1A, 1B and 1C. The blocks of method 200 are exemplary only and additional steps may be performed and/or steps may be omitted. FIGS. 3-8 are illustrative of portions of an exemplary semiconductor structure corresponding to the interim fabrication steps of the method 200.

In an embodiment of the method 200, in a block 202, a semiconductor device such as a transistor is formed on a substrate. The device may be a portion of an IC. Referring to the example of FIG. 3, a substrate 302 is provided having one or more transistors 304 including source/drain regions 306 and gate structures 308 disposed thereon. As discussed above, the transistors 304 may be planar transistors or multi-gate transistors. The substrate may be substantially similar to as discussed above. For example, in an embodiment the semiconductor substrate 302 includes silicon (Si). Alternatively or additionally, substrate 302 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, the substrate 302 includes one or more group III-V materials, one or more group II-IV materials, or combinations thereof. In some implementations, the substrate 302 is a semiconductor-on-insulator substrate, such as a silicon-on-insulator (SOI) substrate, a silicon germanium-on-insulator (SGOI) substrate, or a germanium-on-insulator (GeOI) substrate.

The source/drain regions 306 may be doped regions and/or epitaxially grown regions defining the source/drain feature associated with a gate structure 308 of the semiconductor device. The source/drain regions 306 may be deposited using vapor-phase epitaxy (VPE), ultra-high vacuum CVD (UHV-CVD), molecular beam epitaxy (MBE), and/or other suitable processes. When source/drain region 306 is n-type, it may include silicon (Si) doped with an n-type dopant, such as phosphorus (P) or arsenic (As). When a source/drain region 306 is p-type, it may include silicon germanium (SiGe) doped with a p-type dopant, such as boron (B) or boron difluoride (BF₂). In some embodiments, the source/drain regions 306 may include multiple layers such as layers with different dopant concentrations.

The gate structure 308 includes an interfacial layer, a gate dielectric layer, and a gate electrode. The interfacial layer of the gate structures 308 may include a dielectric material such as silicon oxide, hafnium silicate, or silicon oxynitride. The interfacial layer may be formed by chemical oxidation, thermal oxidation, atomic layer deposition (ALD), chemical vapor deposition (CVD), and/or other suitable method. The gate dielectric layer may be formed on the interfacial layer. The gate dielectric layer may include a high-k dielectric material, such as hafnium oxide. Alternatively, the gate dielectric layer of the gate structures 308 may include other high-K dielectric materials, such as titanium oxide (TiO₂), hafnium zirconium oxide (HfZrO), tantalum oxide (Ta₂O₅), hafnium silicon oxide (HfSiO₄), zirconium oxide (ZrO₂), zirconium silicon oxide (ZrSiO₂), lanthanum oxide (La₂O₃), aluminum oxide (Al₂O₃), zirconium oxide (ZrO), yttrium oxide (Y₂O₃), SrTiO₃ (STO), BaTiO₃ (BTO), BaZrO, hafnium lanthanum oxide (HfLaO), lanthanum silicon oxide (LaSiO), aluminum silicon oxide (AlSiO), hafnium tantalum oxide (HfTaO), hafnium titanium oxide (HfTiO), (Ba,Sr) TiO₃ (BST), silicon nitride (SiN), silicon oxynitride (SiON), combinations thereof, or other suitable material. The gate dielectric layer may be formed by ALD, physical vapor deposition (PVD), CVD, oxidation, and/or other suitable methods. The gate electrode layer of the gate structures 308 may include a single layer or alternatively a multi-layer structure, such as various combinations of a metal layer with a selected work function to enhance the device performance (work function metal layer), a liner layer, a wetting layer, an adhesion layer, a metal alloy, or a metal silicide. By way of example, the gate electrode layer may include titanium nitride (TiN), titanium aluminum (TiAl), titanium aluminum nitride (TiAlN), tantalum nitride (TaN), tantalum aluminum (TaAl), tantalum aluminum nitride (TaAlN), tantalum aluminum carbide (TaAlC), tantalum carbonitride (TaCN), aluminum (Al), tungsten (W), nickel (Ni), titanium (Ti), ruthenium (Ru), cobalt (Co), platinum (Pt), tantalum carbide (TaC), tantalum silicon nitride (TaSiN), copper (Cu), other refractory metals, or other suitable metal materials or a combination thereof.

A dielectric layer 310, also referred to as an inter-layer dielectric (ILD) layer, may be formed on the substrate 302 and adjacent the gate structures 308. The ILD layer 310 may be deposited using PECVD, FCVD, spin-on coating, or a suitable deposition technique. In some embodiments, after formation of the ILD layer 310, the structure may be annealed to improve integrity of the ILD layer 310. Although not explicitly shown in figures it is understood a contact etch stop layer (CESL) may be deposited before the ILD layer 310 is deposited such that the CESL is disposed between the ILD layer 310 and the source/drain features. The CESL may include silicon nitride or silicon oxynitride and may be deposited using CVD, ALD, or a suitable method.

Contact structures 312 extend through the ILD layer 310 to the source/drain regions 306 and the gate structure 308. The contact structures 312 may be referred to as middle-end-of-the-line (MEOL) structures. The contact structures 312 may include ruthenium (Ru), cobalt (Co), nickel (Ni), tungsten (W), copper (Cu), or other metals, as examples. In some embodiments, the contact plugs 312 may include a barrier layer to interface the ILD layer 310. Such a barrier layer may include a metal nitride, such as titanium nitride, tantalum nitride, tungsten nitride, cobalt nitride, or nickel nitride. Additionally, in order to reduce contact resistance, a silicide feature may be a portion of the contact structure 312 and interface the transistor feature such as gate 308. The silicide feature may include titanium silicide. The contact structure 312 may be deposited using CVD, PVD, or a suitable method.

The method 200 then proceeds to block 204 where a multi-layer interconnect (MLI) is formed over the device. Referring to the example of FIG. 3, an MLI 314 is provided that include vias 314B and metal layers 314A formed over the substrate 302. While three (3) metal layers are shown any number for ease of reference, any number of metal layers 314A and interposing vias 314B may be provided. Dielectric 314C interposes the metal layers 314A and vias 314B. The metal layer 314A and via 314B may include copper (Cu). Other compositions include those discussed above titanium (Ti), ruthenium (Ru), nickel (Ni), cobalt (Co), copper (Cu), molybdenum (Mo), tungsten (W), aluminum (Al), or combinations thereof. The dielectric layer 314C may be deposited using PECVD, FCVD, spin-on coating, or a suitable deposition technique. The dielectric layer 314C may include silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In one embodiment, the dielectric layer 314C includes silicon oxide. Each of the MLI 314 features may include a multi-layer structure. As discussed in embodiments below, one or more of the layers of the dielectric layer 314C may include a diamond-like carbon composition. In some embodiments, at least a first dielectric layer 314C is an oxide-based layer (e.g., adjacent the ILD 310) and at least one dielectric layer 314C above the first dielectric layer 314C is a diamond-like carbon composition.

The method 200 then proceeds to block 206 where a thermal dissipation layer is formed over and/or within the multi-layer interconnect. The thermal dissipation layer may be substantially similar to the thermal dissipation layer 104 discussed above with reference to FIGS. 1A, 1B, 1C. In an embodiment, the thermal dissipation layer is a diamond-like carbon layer. In some implementations, the thermal dissipation layer is a poly crystalline carbon providing a diamond-like film or DLC. The thermal dissipation layer may have a thickness of between approximately 0.5 microns (μm) and 10 μm. The thermal dissipation layer may be deposited at a temperature less than or equal to approximately 400 degrees Celsius. Exemplary deposition methods include chemical vapor deposition (CVD) such as microwave plasma (MPCVD).

Referring first to the example of FIGS. 4A-4B, the thermal dissipation layer 104 is formed over the MLI 314. In an embodiment, the thermal dissipation layer 104 is formed interfacing an uppermost dielectric layer 314C is disposed above an uppermost metal line 314A of the MLI 314 as shown in FIG. 4B. In an embodiment, the thermal dissipation layer 104′ is formed over and coplanar with an uppermost metal layer 314A of the MLI 314 as shown in FIG. 4A.

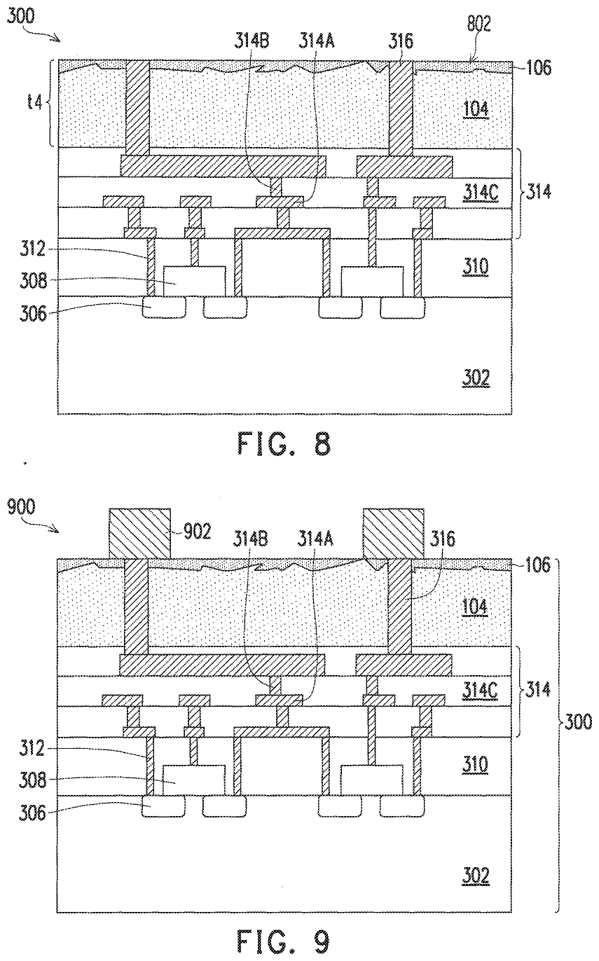

In other examples the material suitable for the thermal dissipation layer 104 (e.g., diamond-like carbon) may also be used as one or more IMD layers 314C within the MLI 314. See e.g., FIG. 10. In some implementations, the dielectric layer corresponding with metal layer four (M4) and above include the thermal dissipation layer 104 as the inter-metal dielectric. As illustrated in FIG. 10, the metal layers 214A and vias 214B are formed within the thermal dissipation layer 104. As illustrated in structure 1000 of FIG. 10, in some implementations over the MLI 314 another thermal dissipation layer 104 is formed. This upper thermal dissipation layer 104 may be thicker than those provided within the MLI 314.

The thermal dissipation layer 104 may have a thickness (t1) of between approximately 0.5 microns (μm) and 10 μm. The thermal dissipation layer 104 may be deposited at a temperature less than or equal to approximately 400 degrees Celsius. Exemplary deposition methods include chemical vapor deposition (CVD) such as microwave plasma (MPCVD). As deposited, the thermal dissipation layer 104 may have a rough top surface, for example, having a roughness of hundreds of nanometers to micrometers in RMS value, or a peak to valley vertical distance.

In an embodiment, the method 200 proceeds to block 208 where a planarization is performed on the thermal dissipation layer. In some implementations, the planarization may include a CMP process or ion milling. In an embodiment, the thermal dissipation layer as deposited includes a surface having a roughness of RMS value of hundreds of nanometers to micrometers and after the planarization the process may decrease the surface roughness by about 10% or 50%. In an embodiment, after planarization the thermal dissipation layer may have a surface having an RMS roughness between approximately 5 nm and approximately 100 nm. In an embodiment, after planarization the thermal dissipation layer may have a surface having an RMS roughness of between 50 and 150 nm. In other embodiments, block 208 is omitted and no planarization process is performed on the thermal dissipation layer 104 prior to materials (e.g., bonding layer discussed below) being deposited thereon.

In an embodiment, block 208 includes in addition to or in lieu of the planarization or ion milling, an oxygen plasma treatment on the surface to provide for a desired surface roughness. The CMP, ion million and/or oxygen plasma may be used to achieve desired interface with the overlying bonding layer (e.g., AlN, c-BN) such as to maximize the performance of the thermal coatings.

The method 200 then proceeds to block 210 where a bonding layer is formed over the thermal dissipation layer. Exemplary compositions of the bonding layer include AlN, cubic BN (c-BN), BP, Al₂O₃, SiN, BeO, SiO₂, or combinations thereof. In some embodiments, the composition of the bonding layer has a high thermal conductivity such as a thermal conductivity (k) greater than or equal to 50 W/m/K for example for thicknesses greater than 200 nm. In an embodiment, the bonding layer is AlN. In a further embodiment, the thermal conductivity (k) of the AlN is >50 W/m/K for thicknesses >200nm. In an embodiment, the bonding layer is c-BN. In a further embodiment, the thermal conductivity (k) of the c-BN is several 100 s W/m/K. The bonding layer may be substantially similar to the bonding layer 106 discussed above with reference to FIGS. 1A, 1B, 1C.

Referring to the example of FIG. 5, a bonding layer 106 is formed over the thermal dissipation layer 104. (It is noted that while the configuration of the thermal dissipation layer 104 of FIG. 4B is illustrated, one would appreciate other configurations of the thermal dissipation layer 104 including that of FIG. 4A or FIG. 10 are also within the scope of this embodiment.) In an embodiment, the bonding layer 106 is formed having a thickness sufficient to fill/overfill each of the valley/peak regions of the surface of the thermal dissipation layer 104. In an embodiment, the bonding layer 106 is deposited conformally such that it covers an entirety of the thermal dissipation layer 104. In an embodiment, the bonding layer 106 is deposited at a temperature less than approximately 400 degrees Celsius. Exemplary deposition methods include chemical vapor deposition (CVD), physical vapor deposition (PVD), or atomic layer deposition (ALD). In some implementations, the bonding layer 106 has a thickness (t2) between approximately 100 nm to 1 μm.

In some embodiments, the method 200 proceeds to block 212 and a planarization process is performed on the bonding layer deposited in block 210. Block 212 may include a CMP, ion milling, other suitable planarization processes, and/or combinations thereof. In an embodiment, the surface of the bonding layer has a roughness RMS of between 5 nm and 100 nm before the planarization process or ion milling process and an RMS of less than approximately 1 nm after planarization. Referring to the example of FIG. 6, the bonding layer 106 has been planarized to form surface 106A. In some implementations, the bonding layer 106 has a thickness (t3) between approximately 10 nm to 1 μm after planarization.

In performing the planarization process of the bonding layer 106, the process may be stopped at a point that is just above the highest peaks of the surface of the thermal dissipation layer 104. In some implementations, the etching rate of the planarization process is used to recognize a stopping point for the process (e.g., when the etching rate slows, the process can be stopped (as it is an indication of the underlying thermal dissipation layer's composition)). In other implementations, a calibrated etch rate of the bonding layer 106 (e.g., AlN) during the CMP process can be used to control the thickness of the bonding layer.

In an embodiment of the method 200, the method proceeds to block 214 where an additional interconnect layer is formed in and/or over the bonding layer. Referring to FIG. 7, a via 316 is formed extending through the bonding layer 106 and the thermal dissipation layer 104. The via 316 interfaces an uppermost metallization (e.g., metal layer 314A) of the MLI 314 to provide an electrical connection. The via 316 may be formed by suitable photolithography and etching processes to form an opening in the thermal dissipation layer 104 and the bonding layer 106, followed by deposition of one of more conductive materials into the opening form the via 316. Example compositions include copper (Cu), titanium (Ti), ruthenium (Ru), nickel (Ni), cobalt (Co), copper (Cu), molybdenum (Mo), tungsten (W), aluminum (Al), tantalum (Ta) or combinations thereof.

In an embodiment, the method 200 continues to block 216 to activate or treat the surface of the bonding layer formed in block 210. The activation or treatment may include preparing the surface for bonding with additional layers or features. In some implementations, a surface treatment or activation process is performed on the bonding layer such as a cleaning process and/or a plasma treatment. In some implementations, functionalization of the surface may be done by surface oxidization, by forming and activation of surface hydroxyl groups, or by deposition of a few nm of an oxide such as SiO₂. In some implementations, the functionalization of the surface may include plasma activation of the bonding layer 106 such as of a AlN surface provided with a plasma treatment of O₂, Ar, SF₆, or combinations thereof, which resulted in a change in the chemical and topography state of the surface. In some implementations, the functionalization of the surface increases hydrophilicity. In some implementations, a cleaning process is performed on a surface of the bonding layer such as a wet cleaning process. In some implementations the cleaning process changes to the state of the surface to increase hydrophilicity. Referring to the example of FIG. 8, an activated surface 802 is illustrated. In some implementations, the activated surface may include AlN, cubic BN, BP, Al₂O₃, SiN, BeO, SiO₂, or combinations thereof, modified to enhance bondability to overlying features (e.g., silicon substrate). In some implementations, block 216 is omitted. As illustrated in FIG. 8, the stack of the thermal dissipation layer 104 and the bonding layer 106, together forming a thermal coating, have a thickness (t4) of between approximately 500 nm and 10 μm.

In some implementations, the method 200 continues to block 218 where additional layers or features are formed on the structure. The additional layers or features may include other semiconductor structures such as other die(s), heat sinks, package features such as input/output terminals (e.g., balls, bumps, pillars), substrates such as semiconductor substrates or interposer substrates, carrier substrates, and/or various other features including those implementing 3D IC structures.

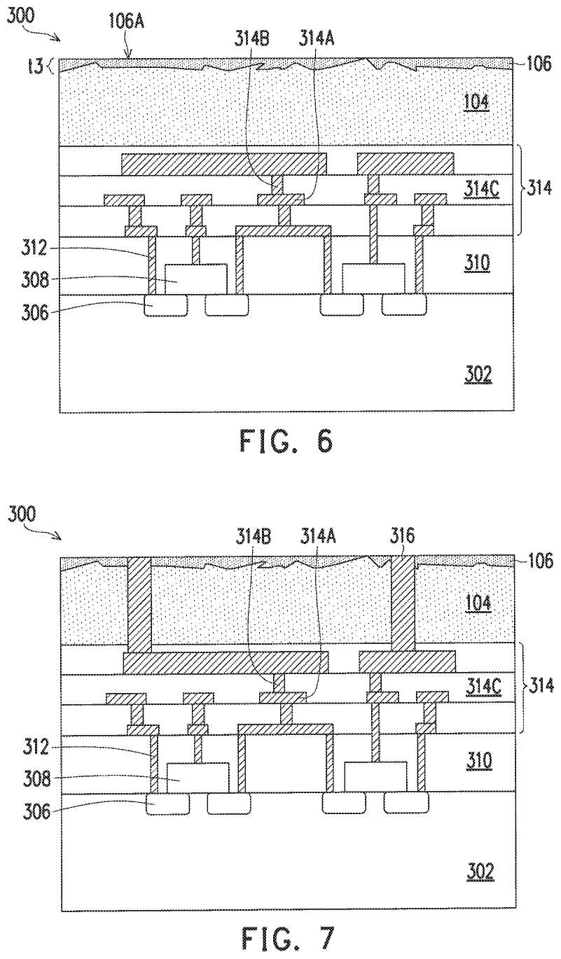

Referring now to FIGS. 9-12 illustrated are semiconductor structures that may be formed using one or more aspects of the method 200 of FIG. 2. Any aspect of any one of the exemplary devices may be used in conjunction with the other embodiments.

Referring to the example of FIG. 9, a semiconductor structure 900 is illustrated that includes a semiconductor substrate 302, semiconductor devices 304, MLI 314, a thermal dissipation layer 104 and a bonding layer 106, which may be substantially similar to as discussed above. The semiconductor structure 900 may be fabricated using aspects of the method 200 of FIG. 2, discussed above. As illustrated in the structure 900, conductive features 902 are provided over the bonding layer 106 and connected to the vias 316. The conductive features 902 may be interconnects such as C4 bump interconnects, pillars (e.g., copper pillars), C3 balls, solder balls, and/or other conductive features. In some implementations, the conductive features are connected to another semiconductor structure such as another die, an interposer substrate, operable for connection to a printed circuit board and/or other packaging structures. Passivation or underfill materials (not shown) may be formed over the bonding layer 106 and adjacent the conductive features 902. The bonding layer 106 may provide an improved adhesion to surrounding materials (e.g., surrounding bump interconnections such as dielectric layers, underfill, passivation layers, and/or the like (not shown) adjacent the conductive features. In some implementations, a chip-stack may include several occurrences of the bonding layer 106 (e.g., between structures of the stack) and for a reduction of in process complexity, the bonding layer 106 may be present on an upper semiconductor structure providing a smoothed surface that may be without additional bonding between the uppermost bonding layer 106 and an overlying material.

Referring to example of FIG. 10, a semiconductor structure 1000 is illustrated that includes a semiconductor substrate 302, semiconductor devices 304 formed on the substrate 302 and an MLI 314 disposed over and connecting the semiconductor devices 304 substantially similar to as discussed above. The semiconductor structure 1000 may be fabricated using aspects of the method 200 of FIG. 2, discussed above. The semiconductor structure 1000 is illustrative of certain dielectric layers of the MLI 314 comprising a thermal dissipation material similar to that of the thermal dissipation layer 104 discussed above. These thermal dissipation material IMD layers are annotated as terminal dissipation IMD layers 104″. As illustrated, upper dielectric layers of the MLI 314 include the thermal dissipation IMD layers 104″ while lower dielectric layers of the MLI 314 are comprise IMD layers 314C. That is, the lower dielectric layers IMD layers 314C of the MLI 314 may include different dielectric materials than the upper dielectric layers 104″ of the MLI 314. In an embodiment, the thermal dissipation IMD layers 104″ of the MLI 314 are diamond-like carbon. And the dielectric 314C of the MLI 314 are one or more of silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In other embodiments, each of the IMD layers of the MLI 314 comprises the thermal dissipation layer material (e.g., diamond-like carbon). It is noted that a thermal dissipation layer 104 is formed over the MLI 314. The bonding layer 106 is formed over the thermal dissipation layer 104. Additional structures (e.g., die, layers, heat sinks, interconnects) may be formed over the bonding layer 106.

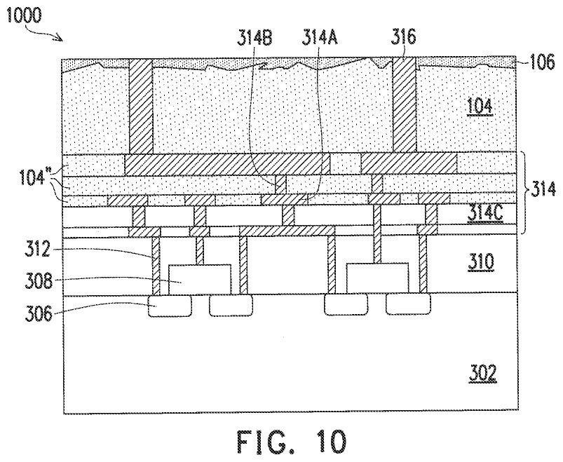

Referring to example FIG. 11, a semiconductor structure 1100 is shown having a second die 1102 provided over the bonding layer 106 of the semiconductor structure 300. The semiconductor structure 300 may be substantially similar to as discussed above with reference to the method 200 and FIGS. 3-8. In an embodiment, the second die 1102 may be substantially similar to the first semiconductor structure 300. In some implementations, the first semiconductor structure 300 and the second die 1102 may comprise a different IC.

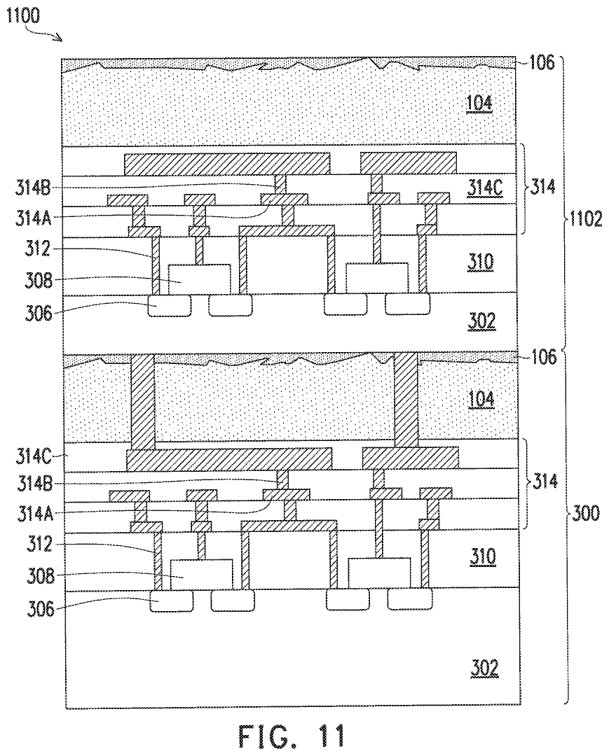

Referring to example FIG. 12, a semiconductor structure 1200 is shown having a second die 1102 provided over the bonding layer 106 of the semiconductor structure 300. The bonding layer 106 of the structure 300 provides a bonding surface suitable for receiving a surface of the die 1102, as discussed above. In an embodiment, a bonding may be provided between the bonding layer 106 and a material of the substrate 302 of the die 1102. In other implementations, additional bonding or dielectric layers may be presented on a lower surface of the substrate 302 and interface with the bonding layer 106. The semiconductor structure 300 may be substantially similar to as discussed above with reference to the method 200 and FIGS. 3-8. In an embodiment, the second die 1102 may be substantially similar to the first semiconductor structure 300. In some implementations, the first semiconductor structure 300 and the second die 1102 may comprise a different IC. Over the second die 1102 including its thermal dissipation layer 104 and bonding layer 106 is an additional component 1202. In an embodiment, the additional component 1202 is another die such as another die substantially similar to the semiconductor structure 300 and/or the die 1102. In an embodiment, the additional component 1202 is another IC device including a die having a different functionality and/or footprint than the structure 300 and/or the die 1102. In an embodiment, the additional component 1202 is a carrier substrate such as a glass substrate. In an embodiment, the additional component 1202 is another substrate. In some embodiments, the component 1202 includes a silicon (Si) substrate. Alternatively or additionally, component 1202 includes another elementary semiconductor, such as germanium (Ge); a compound semiconductor, such as silicon carbide, gallium arsenide, gallium phosphide, indium phosphide, indium arsenide, and/or indium antimonide; an alloy semiconductor, such as silicon germanium (SiGe), GaAsP, AlInAs, AlGaAs, GaInAs, GaInP, and/or GaInAsP; or combinations thereof. In some implementations, component 504 includes one or more group III-V materials, one or more group II-IV materials, or combinations thereof. In some implementations, the component 1202 is a semiconductor-on-insulator substrate, such as a silicon-on-insulator (SOI) substrate, a silicon germanium-on-insulator (SGOI) substrate, or a germanium-on-insulator (GeOI) substrate.

Semiconductor-on-insulator substrates can be fabricated using separation by implantation of oxygen (SIMOX), wafer bonding, and/or other suitable methods. In an embodiment, the component 1202 is a heatsink. The heatsink may include a thermally conductive plate (e.g., copper or aluminum), coolant in piping, and/or another other configurations.

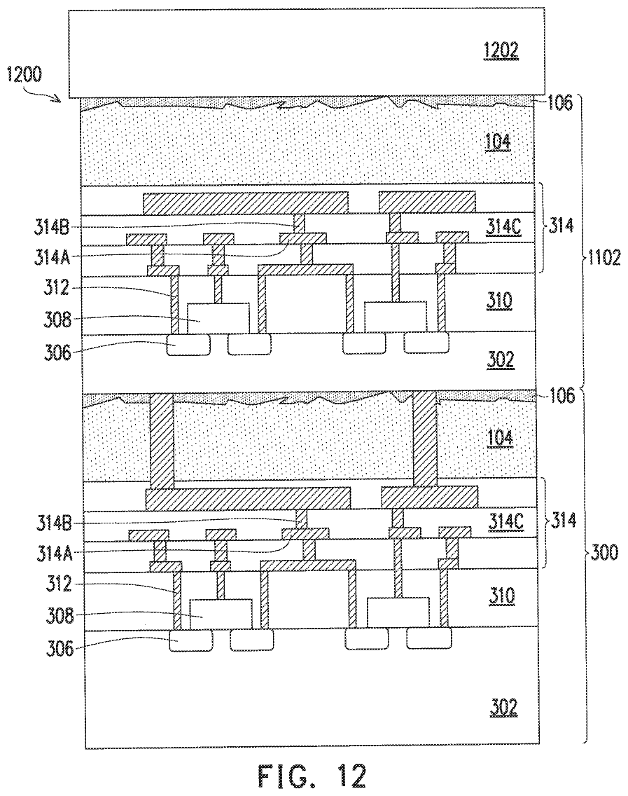

Referring to example FIG. 13, a semiconductor structure 1300 is shown having a second die 1302 provided over the bonding layer 106 of the semiconductor structure 1000. In an embodiment, the second die 1302 may be substantially similar to the first semiconductor structure 1000. The semiconductor structure 1000 may be substantially similar as discussed above with reference to the similarly labeled structure of FIG. 10. The semiconductor structure 1302 may also be substantially similar as shown above. As discussed above, thermal dissipation material IMD layers are provided in upper dielectric layers of the MLI while lower dielectric layers of the MLI are comprise IMD layers having a different composition (e.g., not comprising a thermal material similar to that of layer 104.) In an embodiment, the thermal dissipation IMD layers of the MLI are diamond-like carbon and the dielectric of the lower layers of the MLI are one or more of silicon oxide, tetraethylorthosilicate (TEOS) oxide, un-doped silicate glass (USG), or doped silicate glass such as borophosphosilicate glass (BPSG), fused silicate glass (FSG), phosphosilicate glass (PSG), boron doped silicate glass (BSG), and/or other suitable dielectric materials. In some implementations, the first semiconductor structure 1000 and the second die 1302 may comprise a different IC. It is noted that combinations stacking the semiconductor structure 300 and the second die 1302 are also possible.

It is noted that electrical connections may be provided between lower and upper die of a semiconductor structure stack such as illustrated in FIGS. 11-13 that are not shown. One exemplary manner in providing these electrical connections is by through substrate via (TSV). Other means may also be possible.

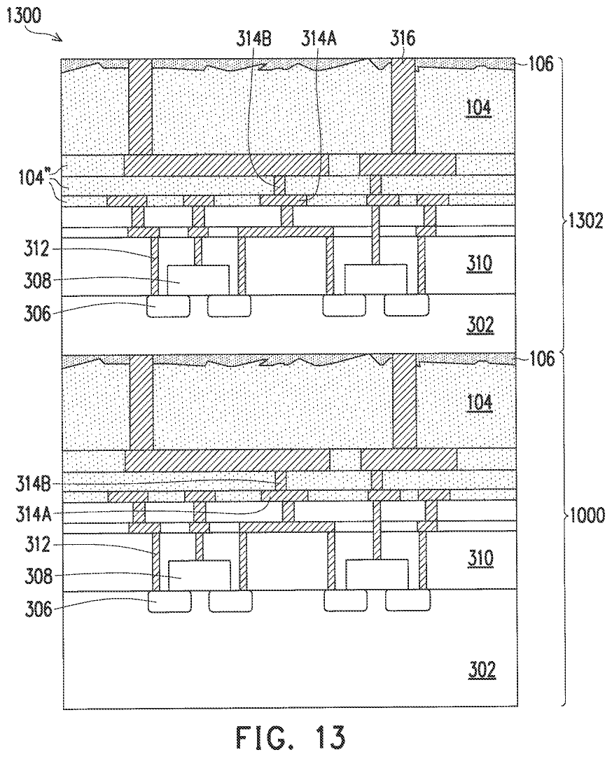

FIG. 14 is illustrative of an embodiment of a portion of a semiconductor structure 1400 according to aspects of the present disclosure. The structure 1400 shares similar features the structure 100 of FIG. 1 discussed above. The structure 1400 includes a first metal layer 102, which may be substantially similar to as discussed above with reference to FIGS. 1A, 1B, and 1C. In some implementations, the metallization layer 102 is an uppermost metal layer of an MLI of a first structure (e.g., die). A thermal dissipation layer 104 is formed over the metallization layer 102. The thermal dissipation layer 104 may be substantially similar as discussed above. For example, in some implementations, the thermal dissipation layer is a diamond-like carbon material (amorphous carbon). The thermal dissipation layer 104 includes an upper surface having a roughness exhibiting peaks and valleys. As discussed above, the upper surface may include an RMS of hundreds of nanometers or more. A bonding layer 106 is formed on the upper surface of the thermal dissipation layer 104 including in covering the peaks and valleys of the surface. The bonding layer 106 may be substantially similar to as discussed above with reference to FIGS. 1A, 1B, and 1C. In the illustrated embodiment, the thermal dissipation layer 104 is completely embedded within the bonding layer 106. In other words, no portion of the thermal dissipation layer 104 extends above a top surface of the bonding layer 106. An additional bonding layer 1402 is formed over the bonding layer 106. The additional bonding layer 1402 may be deposited after planarization of the bonding layer 106 such as the planarization discussed above with reference to block 212 of the method 200 of FIG. 2. In an embodiment the bonding layer 1402 is one or more of AlN, cubic BN (c-BN), BP, Al₂O₃, SiN, BeO, SiO₂, or combinations thereof. In an embodiment, the bonding layer 1402 is a different material than the bonding layer 106. A metallization layer 108 is formed over the bonding layer 1402. The metallization layer 108 may be substantially similar to as discussed above with reference to FIGS. 1A, 1B, 1C. In some implementations, the metallization layer 108 is a layer of a different structure (e.g., different die) than the metallization layer 102. In other implementations, the metallization layer 108 is another feature such as a substrate, dielectric layer, heatsink, etc. As illustrated in an embodiment, at least one point of the bonding layer 106 has a top surface approximately substantially coplanar with a peak of the thermal dissipation layer 104. See “A.” As illustrated in an embodiment, at least one point of the bonding layer 106 has a top surface exactly coplanar with a peak of the thermal dissipation layer 104.

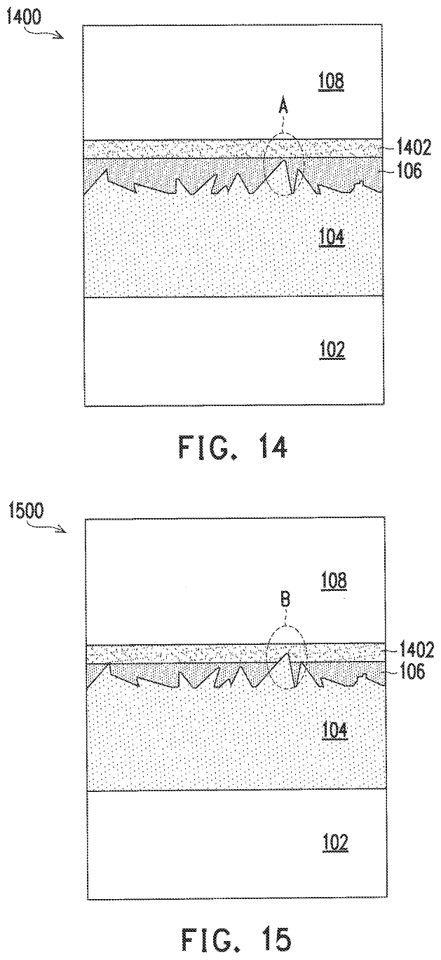

FIG. 15 is illustrative of an embodiment of a portion of a semiconductor structure 1500 according to aspects of the present disclosure. The structure 1500 shares similar features the structure 100 of FIG. 1 discussed above. The structure 1500 includes a first metal layer 102, which may be substantially similar to as discussed above with reference to FIGS. 1A, 1B, and 1C. In some implementations, the metallization layer 102 is an uppermost metal layer of an MLI of a first structure (e.g., die). A thermal dissipation layer 104 is formed over the metallization layer 102. The thermal dissipation layer 104 may be substantially similar as discussed above. For example, in some implementations, the thermal dissipation layer is a diamond-like carbon material (amorphous carbon). The thermal dissipation layer 104 includes an upper surface having a roughness exhibiting peaks and valleys. As discussed above, the upper surface may include an RMS of hundreds of nanometers or more. A bonding layer 106 is formed on the upper surface of the thermal dissipation layer 104 including in covering the peaks and valleys of the surface. The bonding layer 106 may be substantially similar to as discussed above with reference to FIGS. 1A, 1B, and 1C. In the illustrated embodiment, the thermal dissipation layer 104 extends through and above the bonding layer 106. In other words, a portion of the thermal dissipation layer 104 extends above a top surface of the bonding layer 106. See “B.” An additional bonding layer 1402 is formed over the bonding layer 106. The additional bonding layer 1402 may be deposited after planarization of the bonding layer 106 such as the planarization discussed above with reference to block 212 of the method 200 of FIG. 2. In some implementation, due to the etching difference in the bonding layer 106 and the thermal dissipation layer 104, the peak of the thermal dissipation layer 104 remains extending above the planarized surface of the bonding layer 106. In other embodiments, the bonding layer 106 is not planarized prior to deposition of another layer 9 e.g., bonding layer 1402). In an embodiment the bonding layer 1402 is one or more of AlN, cubic BN (c-BN), BP, Al₂O₃, SiN, BeO, SiO₂, or combinations thereof. In an embodiment, the bonding layer 1402 is a different material than the bonding layer 106. A metallization layer 108 is formed over the bonding layer 1402. The metallization layer 108 may be substantially similar to as discussed above with reference to FIGS. 1A, 1B, 1C. In some implementations, the metallization layer 108 is a layer of a different structure (e.g., different die) than the metallization layer 102. In other implementations, the metallization layer 108 is another feature such as a substrate, dielectric layer, heatsink, etc.

Thus, provided are structures and methods that allow for stacking features such as in a 3D IC configuration having a thermal dissipation layer within the stack. Although not limiting, the present disclosure offers advantages for IC semiconductor structures with thermal dissipation layers having a bonding layer integrated with the top surface of the thermal dissipation layer to provide for an improved bonding surface. One example advantage is providing a planar bonding surface with decreased roughness in comparison with a diamond-based layer.

In one of the broader embodiments, an integrated circuit (IC) structure is described including a transistor device formed on a substrate where the transistor device having source/drain (S/D) regions and a gate structure. A multi-layer interconnect (MLI) structure is formed over the transistor device, wherein the MLI includes metal lines and metal vias embedded in an intermetal dielectric (IMD) layer. A thermal dissipation layer is formed having a surface with a plurality of peaks and valleys disposed over at least a portion of the MLI structure. And a bonding layer over the thermal dissipation layer and covering the plurality of peaks and valleys.

In a further embodiment, the bonding layer has a first surfacing having a root mean square (RMS) value of less than the RMS value of the surface of the thermal dissipation layer. In an embodiment, the first surface has an RMS value of less than 1 nanometer. In an implementation, the thermal dissipation layer is a diamond-like material. In some examples, the surface with the plurality of peaks and valleys has an RMS value of hundreds of nanometers to micrometers in peak to valley height. In an embodiment, the bonding layer is AlN. In an embodiment, the thermal dissipation layer includes at least one additional peak that extends above a top surface of the bonding layer. In some implementations of the structure, the plurality of peaks and valleys of the thermal dissipation layer are entirely covered by the bonding layer. In an embodiment, the bonding layer includes at least one of AlN, cubic BN (c-BN), BP, Al₂O₃, SiN, BeO, or SiO₂.

In another of the broader embodiments, a method of semiconductor device fabrication is provided. The method includes forming a transistor on a semiconductor substrate and forming a first metal layer and an overlying second metal layer over the transistor. A via may extend between the first metal layer and the overlying second metal layer. The method may further include depositing a thermal dissipation layer over the overlying second metal layer while the thermal dissipation layer includes a rough surface exhibiting peaks and valleys. A bonding layer is deposited over the rough surface such that the bonding layer covers at least one peak and valley of the rough surface. And another substrate may be formed over the bonding layer.

In a further embodiment, the method includes planarizing a surface of the bonding layer after the depositing. In an embodiment, depositing the bonding layer includes at least one of AlN, cubic BN (c-BN), BP, Al₂O₃, SiN, BeO, or SiO₂. And depositing the thermal dissipation layer may include depositing diamond-like carbon. In some implementations of the method prior to depositing the thermal dissipation layer, a third metal layer is formed over the overlying second metal layer and a fourth metal layer is formed over the third metal layer. Another via may extend between the third metal layer and the fourth metal layer. In an embodiment, a diamond-like carbon material is deposited surrounding the third metal layer, the fourth metal layer, and the another via.

In another of the broader embodiments, a method is discussed. The method includes forming a transistor device on a substrate, forming a multi-layer interconnect (MLI) over the transistor device, depositing a diamond-like carbon layer over the MLI, depositing a bonding layer on the diamond-like carbon layer, and planarizing the bonding layer to form a planarized surface. The diamond-like carbon layer has surface having an RMS of the surface of at least a hundred nanometers.

In a further embodiment, the method includes providing a die on the planarized surface. The bonding layer may be AlN or c-BN. In an embodiment, the method includes forming an interconnect extending through the diamond-like carbon layer and the bonding layer. In some further implementations, the interconnect is connected to a metal layer of the MLI. In an embodiment, the method also includes depositing another bonding layer over the bonding layer, wherein at least one peak of the surface of the diamond-like carbon layer extends into the another bonding layer.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure, comprising:
a transistor device formed on a substrate, the transistor device having source/drain (S/D) regions and a gate structure;
a multi-layer interconnect (MLI) structure over the transistor device, wherein the MLI includes metal lines and metal vias embedded in an intermetal dielectric (IMD) layer;
a thermal dissipation layer having a surface with a plurality of peaks and valleys disposed over at least a portion of the MLI structure; and
a bonding layer over the thermal dissipation layer and covering the plurality of peaks and valleys.

2. The IC structure of claim 1, wherein the bonding layer has a first surfacing having a root mean square (RMS) value of less than the RMS value of the surface of the thermal dissipation layer.

3. The IC structure of claim 2, wherein the first surface of the bonding layer has an RMS value of less than 1 nanometer.

4. The IC structure of claim 1, wherein the thermal dissipation layer is a diamond-like material.

5. The IC structure of claim 4, wherein the surface with the plurality of peaks and valleys has an RMS value of hundreds of nanometers to micrometers in peak to valley height.

6. The IC structure of claim 1, wherein the bonding layer is AlN.

7. The IC structure of claim 1, wherein the thermal dissipation layer includes at least one additional peak that extends above a top surface of the bonding layer.

8. The IC structure of claim 1, wherein each of the plurality of peaks and valleys are entirely covered by the bonding layer.

9. The IC structure of claim 1, the bonding layer includes at least one of AlN, cubic BN (c-BN), BP, Al₂O₃, SiN, BeO, or SiO₂.

10. A method of semiconductor device fabrication, comprising:
forming a transistor on a semiconductor substrate;
forming a first metal layer and an overlying second metal layer over the transistor, wherein a via extends between the first metal layer and the overlying second metal layer;
depositing a thermal dissipation layer over the overlying second metal layer, wherein the thermal dissipation layer includes a rough surface exhibiting peaks and valleys;
depositing a bonding layer over the rough surface, wherein the bonding layer covers at least one peak and valley of the rough surface; and
forming another substrate over the bonding layer.

11. The method of claim 10, further comprising:
planarizing a surface of the bonding layer after the depositing.

12. The method of claim 10, wherein the depositing the bonding layer includes at least one of AlN, cubic BN (c-BN), BP, Al₂O₃, SiN, BeO, or SiO₂.

13. The method of claim 12, wherein the depositing the thermal dissipation layer includes depositing diamond-like carbon.

14. The method of claim 10, further comprising:
prior to depositing the thermal dissipation layer, forming a third metal layer over the overlying second metal layer and a fourth metal layer over the third metal layer, wherein another via extends between the third metal layer and the fourth metal layer; and
depositing a diamond-like carbon material surrounding the third metal layer, the fourth metal layer, and the another via.

15. A method comprising:
forming a transistor device on a substrate;
forming a multi-layer interconnect (MLI) over the transistor device;
depositing a diamond-like carbon layer over the MLI, wherein the diamond-like carbon layer has surface having an RMS of the surface of at least a hundred nanometers;
depositing a bonding layer on the diamond-like carbon layer; and
planarizing the bonding layer to form a planarized surface.

16. The method of claim 15, further comprising:
providing a die on the planarized surface.

17. The method of claim 15, wherein the bonding layer is AlN or c-BN.

18. The method of claim 15, further comprising:
forming an interconnect extending through the diamond-like carbon layer and the bonding layer.

19. The method of claim 18, wherein the interconnect is connected to a metal layer of the MLI.

20. The method of claim 15, further comprising:
depositing another bonding layer over the bonding layer, wherein at least one peak of the surface of the diamond-like carbon layer extends into the another bonding layer.
